(19) United States
(12) Patent Application Publication
(10) Pub. No.: US 2010/0265614 A1
(43) Pub. Date: Oct. 21, 2010

(54) SERVO PATTERN WRITING METHOD OF HARD DISK DRIVE

(75) Inventors: Ha Yong KIM, Seoul (KR); Cheol-Soon KIM, Anyang-si (KR); Yong-Soo KIM, Seoul (KR); Sang-Hyun PARK, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 12/761,186

(22) Filed: Apr. 15, 2010

(30) Foreign Application Priority Data
Apr. 16, 2009 (KR) 10-2009-0033315

(51) Int. Cl. G11B 21/02; G03F 7/20

(52) U.S. Cl. 360/75; 430/319; G9B/21.003

(57) ABSTRACT

A method of writing a servo pattern in a hard disk drive includes manufacturing a master pattern, and writing the reference servo pattern to the disk by using the master pattern and a magnet for magnetizing the disk. The master pattern includes a plurality of ammonite cycles that have substantially the same pattern as the reference servo pattern and are radially formed from the outside toward the inside of the disk. A final servo pattern may be written using the reference servo pattern.

### CROSS-REFERENCE TO RELATED APPLICATIONS

This application claims priority from Korean Patent Application No. 10-2009-0033315, filed on Apr. 16, 2009, in the Korean Intellectual Property Office, the disclosure of which is incorporated herein in its entirety by reference.

### SUMMARY

Exemplary embodiments relate to a method of writing a servo pattern in a hard disk drive, and more particularly, to a method of writing a servo pattern in a hard disk drive by which not only the time and cost to write a reference servo pattern to a disk of an HDD may be reduced, but a reference servo pattern desired by a user may be conveniently written.

According to an aspect of an exemplary embodiment, there is provided a method of writing a servo pattern on a disk, which comprises manufacturing a master pattern, and writing a reference servo pattern to the disk by using the master pattern and a magnet for magnetizing the disk, in which the master pattern includes a plurality of ammonite cycles that have substantially the same pattern as the reference servo pattern and are radially formed from an outer circumferential limit to an inner circumferential limit.

The method may further include writing a final servo pattern to the disk by using the reference servo pattern, after the reference servo pattern is written.

The reference servo pattern may include a plurality of bits arranged at a regular interval, and a plurality of sync bits formed between the plurality of bits.

The ammonite cycles may include a plurality of cycle patterns, each including a plurality of bits arranged at the regular interval, and a plurality of sync patterns, each formed between a pair of the plurality of cycle patterns and each including a plurality of sync bits.

The size of each of the sync bits may be half of the size of each of the bits of the cycle patterns.

The ammonite cycles may be continuously formed.

The ammonite cycles may be intermittently formed only in a servo sampling section.

The manufacturing of a master pattern may include coating a photoresist layer on a substrate, exposing the photoresist layer to light, developing the photoresist layer to selectively remove an exposed portion of the photoresist layer, and pouring a mold onto the substrate where the photoresist layer is removed and hardening the mold.

Exposing the photoresist layer to light may include exposing using an electron beam (E-beam).

### BRIEF DESCRIPTION OF THE DRAWINGS

The above and/or other aspects will be more clearly understood from the following detailed description of exemplary embodiments taken in conjunction with the accompanying drawings in which:

FIG. 1 is a partially exploded perspective view of an HDD employing a method of writing a servo pattern in an HDD according to an exemplary embodiment;

FIG. 2 is a plan view schematically illustrating a disk area of the HDD of FIG. 1;

FIG. 3 illustrates the data format of a track in the HDD of FIG. 1;

FIG. 4 illustrates the detailed structure of the servo sector of FIG. 3;

FIG. 5 is a flowchart for explaining a method of writing a servo pattern in an HDD according to an exemplary embodiment;

FIG. 6 schematically illustrates the shape of a master pattern of FIG. 5;

FIG. 7 is an enlarged view of a portion A of FIG. 6;

FIG. 8 schematically illustrates the principle of an operation to write a reference servo pattern to a disk of an HDD by using the master pattern of FIG. 5;

FIG. 9 schematically illustrates the principle of an operation to write a final servo pattern by using the reference servo pattern formed on a disk; and

FIG. 10 schematically illustrates the principle of an operation to write a final servo pattern by using the reference servo pattern formed on a disk, according to another exemplary embodiment.

### DETAILED DESCRIPTION OF EXEMPLARY EMBODIMENTS

Hereinafter, exemplary embodiments will be described in detail with reference to the attached drawings. Like reference numerals in the drawings denote like elements.

Hard disk drives (HDDs) are data storage devices capable of recording data on a disk or reproducing data stored on the disk using a read/write head. HDDs are widely used as auxiliary memory devices for computer systems because they can access a lot of data at high speeds.

Performing an operation to normally read or write data in the HDD starts from reading a servo pattern written to a servo track of a disk and accessing an accurate position on the disk. The servo pattern is generally written to a disk by using a servo writer. A method of writing a servo pattern on a disk by using a servo writer has drawbacks in that an accuracy of the writing is deteriorated due to non-repeatable run out (NRRO), disk flutter, and motor vibrations, and costs related to the servo writing process are increased due to the use of a position setter and an encoder.

To address the above issues, a self servo track write (SSTW) method has been developed, in which reference servo information is written to a disk in a primary operation and an HDD writes final servo information in a secondary operation by referring to the reference servo information. Recently, of the self servo writing methods, a study on a method of writing a reference servo pattern to a disk by using printed media (PM) is under development. However, a reference servo pattern writing method using the PM that can improve the quality of a servo pattern and simultaneously be capable of mass productivity has not yet been developed.

Thus, there is a demand to develop a servo pattern writing method using PM that may reduce the time and cost of writing a reference servo pattern to a disk of an HDD and can simultaneously make the writing of a reference servo pattern that is desired by a user, convenient.

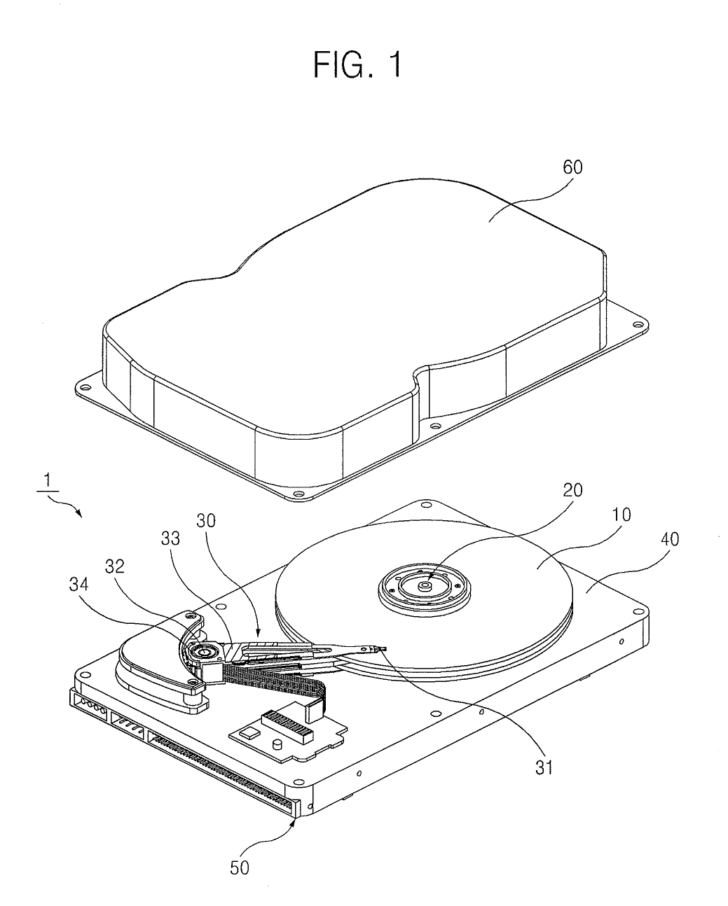

FIG. 1 is a partially exploded perspective view of an HDD 1 employing a method of writing a servo pattern in an HDD according to an exemplary embodiment. Referring to FIG. 1, the HDD 1 according to the present exemplary embodiment includes a disk 10, a spindle motor 20 for supporting and rotating the disk 10, a head stack assembly (HSA) 30 for recording data on the disk 10 or reading data from the disk 10, a base 40 on which the constituent elements are assembled, a printed circuit board assembly (PCBA) 50, on which most circuit parts are installed, coupled to a lower portion of the base 40 to control various elements, and a cover 60 for covering an upper portion of the base 40.

The HSA 30, as a carriage to record data on the disk 10 or read the data recorded on the disk 10, includes a read/write head 31 to write data to the disk 10 or read the written data, an actuator arm 33 pivoting around a pivot shaft 32 across the disk 10 to allow the read/write head 31 to access data on the disk 10, a pivot shaft holder 34 rotatably supporting the pivot shaft 32 and supporting the actuator arm 33 that is coupled thereto, and a bobbin (not shown) provided at the opposite side of the actuator arm 33 with respect to the pivot shaft holder 34 and having a voice coil wound therearound and located between magnets of a voice coil motor (VCM).

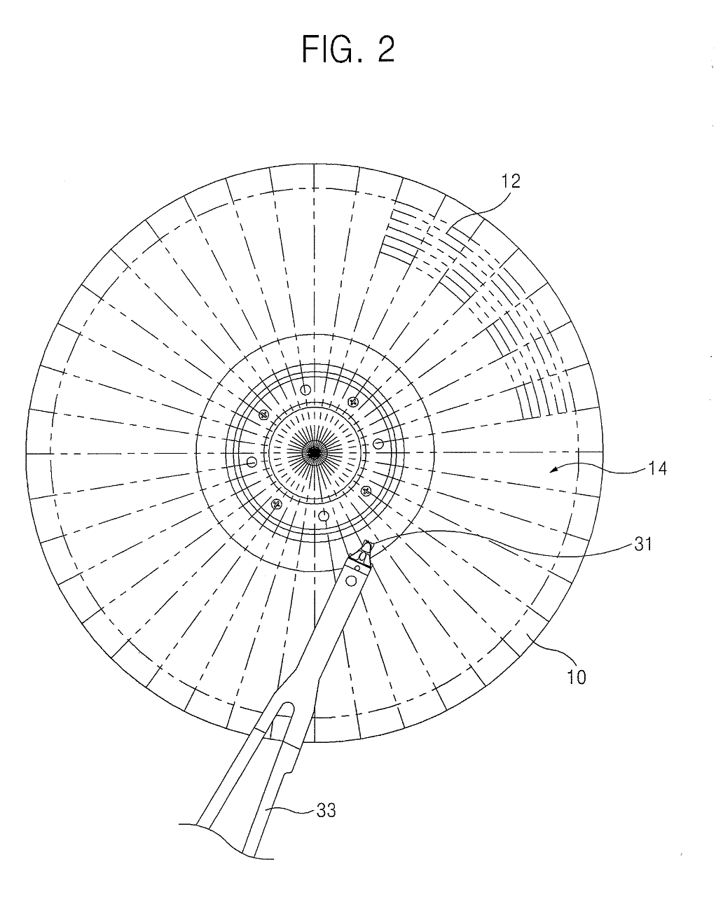

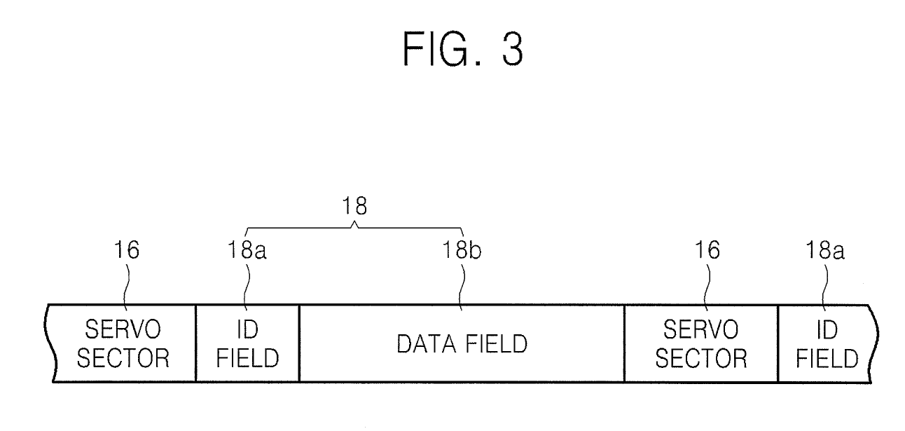

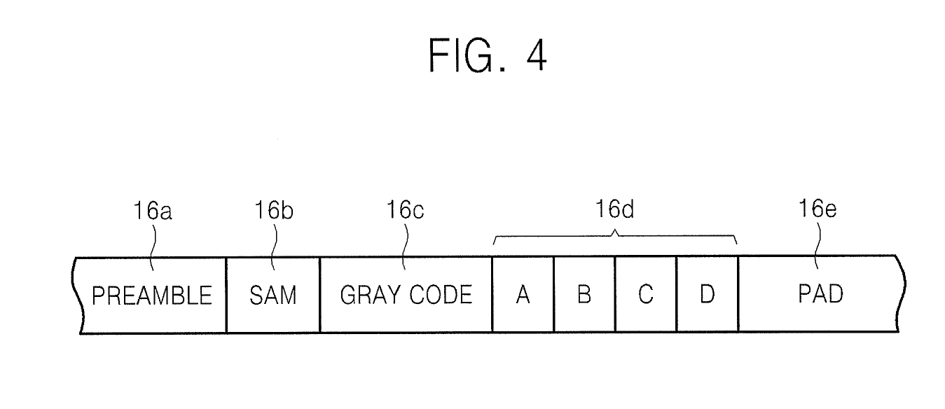

FIG. 2 is a plan view schematically illustrating a disk area of the HDD of FIG. 1. FIG. 3 illustrates the data format of a track in the HDD of FIG. 1. FIG. 4 illustrates the detailed structure of the servo sector of FIG. 3.

A track 12 is a circular area where servo information and data information are stored, and a sector 14 is a basic unit obtained by equiangularly dividing the track 12 with respect to a rotation center, are formed on the disk 10 for recording and storing data, as illustrated in FIG. 2. A servo sector 16 for servo control, such as track seeking or track following, and a data sector 18 for recording user data, are alternately arranged on the track 12, as illustrated in FIG. 3. The servo sector 16, as illustrated in FIG. 4, includes a preamble 16a, a servo address mark (SAM) 16b, a gray code 16c, bursts A, B, C, and D 16d, and a PAD 16e.

The preamble 16a, which is referred to as a servo sync, provides a clock sync during reading of a servo pattern and simultaneously provides a gap at the front of the servo sector to indicate the servo sector. The SAM 16b provides a sync to indicate a start of the servo and the reading of the gray code 16c that follows. That is, the SAM 16b is provided as a reference point to generate various timing pulses related to servo control. The gray code 16c provides information about the track 12, that is, track information. The bursts A, B, C, and D 16d provide a position error signal (PES) needed for the track seeking and track following. Most of the bursts A, B, C, and D 16d are written directly by the read/write head 31 in the HDD 1, except for being written as a seed servo pattern. Finally, the PAD 16e provides a transition margin between the servo sector 16 to the data sector 18.

The data sector 18 is located between servo sectors 16 and is divided into an ID field 18a and a data field 18b. Header information to identify the data sector 18 corresponding thereto is recorded in the ID field 18a. Digital data that a user desires to record is recorded in the data field 18b.

To read the digital data recorded in the data field 18b by using the read/write head 31, or to write digital data to the data field 18b by using the read/write head 31, the read/write head 31 is selectively positioned at a particular track. To selectively position the read/write head 31 at the particular track, the servo pattern existing in the servo sector 16 is read. Thus, the servo pattern is very important in reading and writing of data.

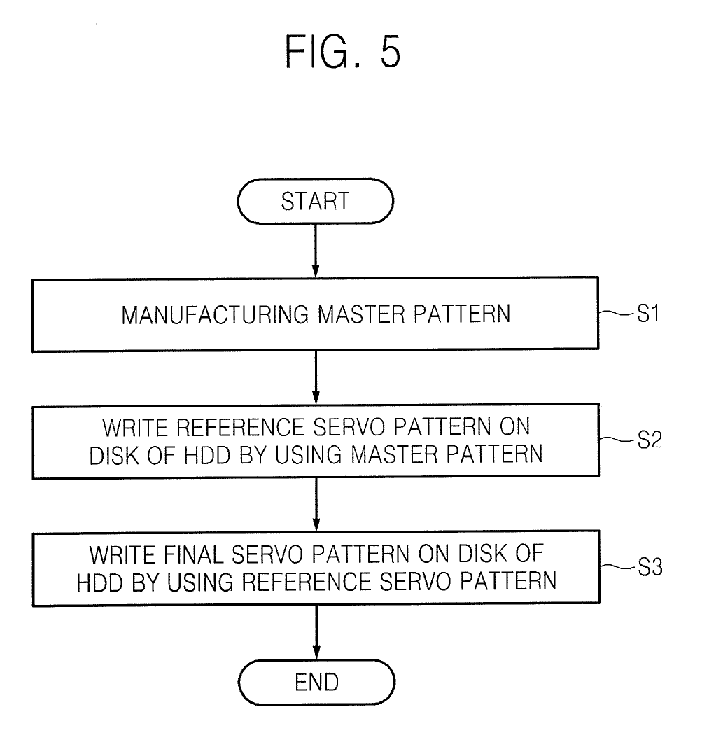

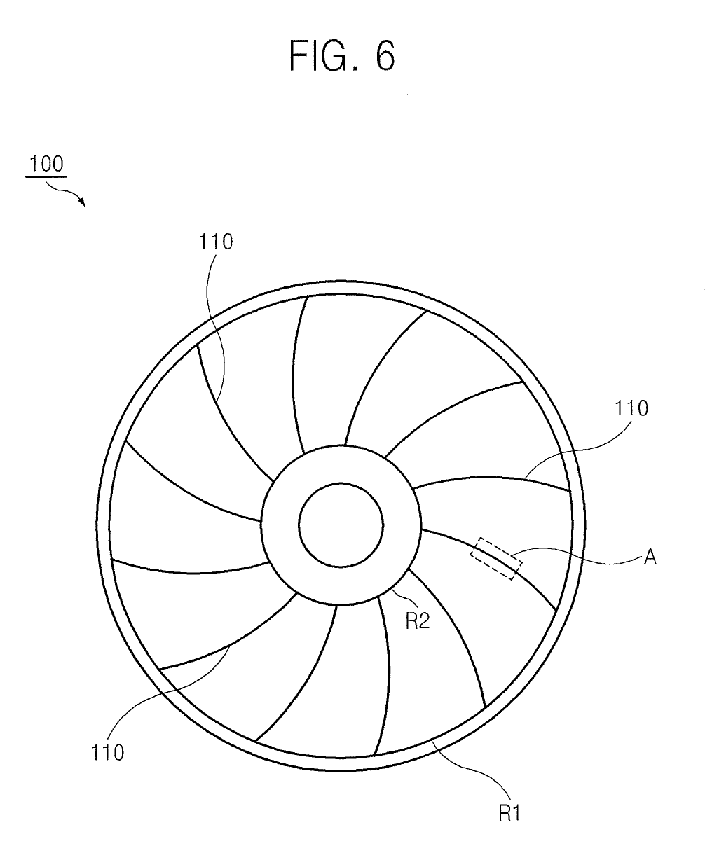

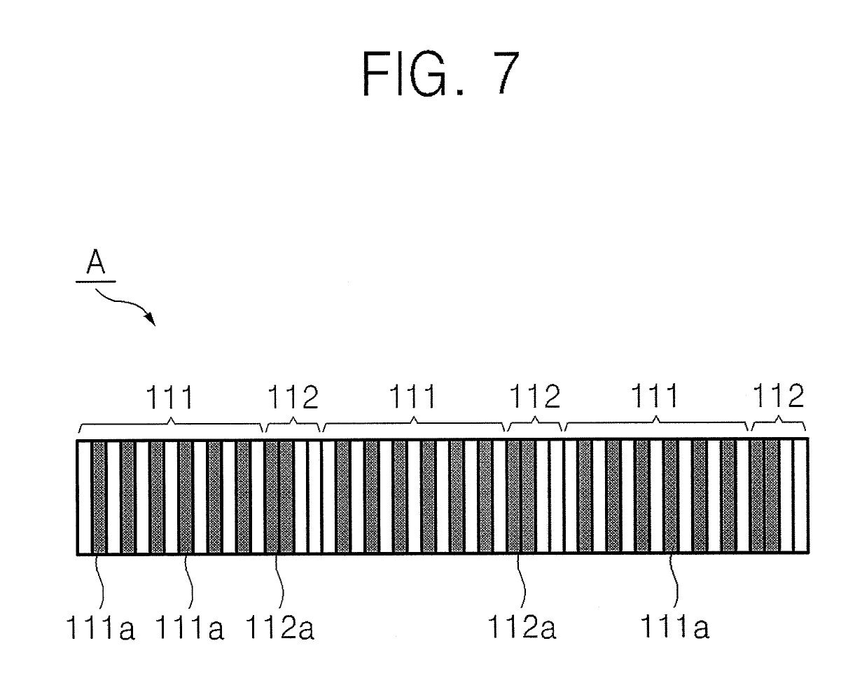

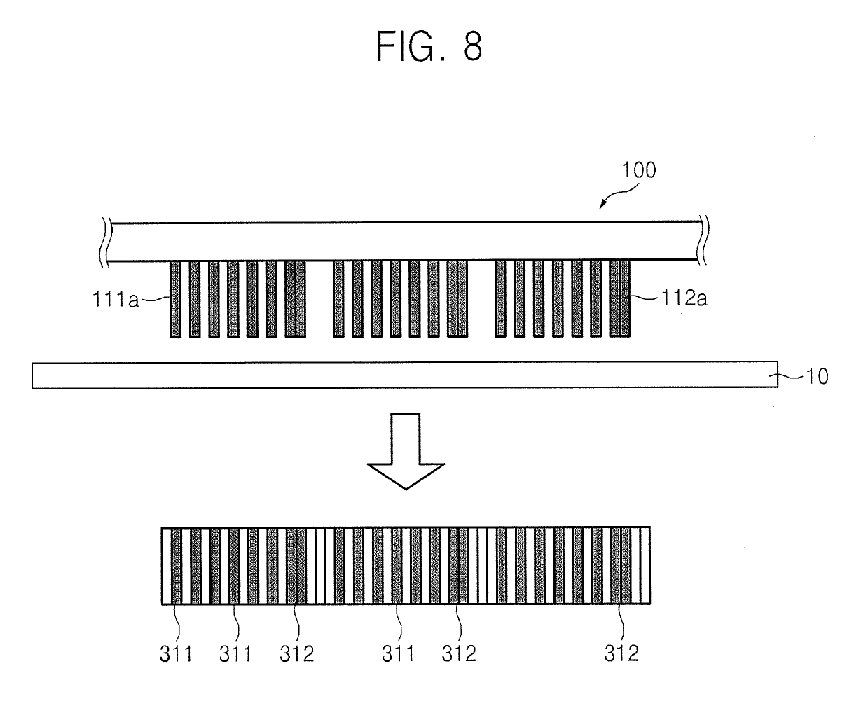

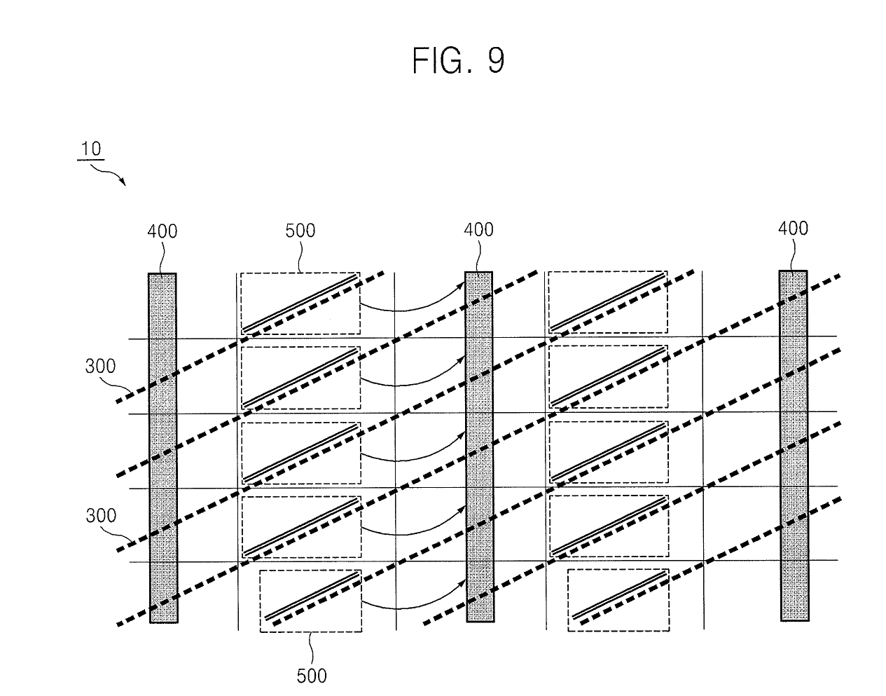

FIG. 5 is a flowchart for explaining a method of writing a servo pattern in an HDD according to an exemplary embodiment. FIG. 6 schematically illustrates the shape of a master pattern of FIG. 5. FIG. 7 is an enlarged view of a portion A of FIG. 6. FIG. 8 schematically illustrates the principle of an operation to write a reference servo pattern to a disk of an HDD by using the master pattern of FIG. 5. FIG. 9 schematically illustrates the principle of an operation to write a final servo pattern by using the reference servo pattern formed on a disk.

Referring to FIGS. 5-9, the method of writing a servo pattern in an HDD according to the present exemplary embodiment includes the operations of manufacturing a master pattern (S1), writing a reference servo pattern to a disk of the HDD by using the master pattern (S2), and writing a final servo pattern to a disk of the HDD by using the reference servo pattern (S3).

In the manufacturing of a master pattern (S1), a master pattern 100, to be used to write a reference servo pattern 300 (refer to FIG. 9) to the disk 10 of the HDD 1, is manufactured. The master pattern 100 refers to a printed medium in which a pattern substantially the same as the reference servo pattern to be formed on the disk 10 is formed. As illustrated in FIG. 6, a plurality of ammonite cycles 110 are radially formed from the outer side to the inner side of the disk.

The master pattern 100 is manufactured by coating a photoresist layer on a substrate formed of a material such as glass, exposing the coated photoresist layer to light to change the properties of the exposed photoresist layer, selectively removing the photoresist layer through a developing process, pouring a mold such as silicon onto a remaining portion after the photoresist layer is selectively removed, and hardening the mold. In the present exemplary embodiment, an electron beam (E-beam) may be used in the process of exposing the coated photoresist layer. Accordingly, a pattern desired by a user may be accurately and conveniently formed.

However, the scope of the present exemplary embodiment is not limited to the above-described manufacturing method of the master pattern 100. For example, the master pattern 100 may be manufactured by depositing a metal layer formed of a material such as chromium (Cr) or aluminum (Al) on a substrate, coating a photoresist layer on the metal layer, developing a fine pattern by emitting an E-beam onto the photoresist layer to change the properties of the photoresist layer receiving the E-beam, removing the photoresist layer, etching the substrate, pouring a mold such as silicon onto a remaining portion after the metal layer is removed, and hardening the mold.

The ammonite cycles 110 formed in the master pattern 100, as illustrated in FIG. 6, are radially formed between an outer circumferential limit R1 and an inner circumferential limit R2 of the master pattern 100. The outer circumferential limit R1 and the inner circumferential limit R2 denote points corresponding to limit points of the tracks 12 where the reference servo pattern 300 may be written to the disk 10.

Each of the ammonite cycles 110, as illustrated in FIG. 7, includes a plurality of cycle patterns 111, each including a plurality of bits 111a arranged in the same interval, and a plurality of sync patterns 112, each being formed between adjacent cycle patterns 111 and having a plurality of sync bits 112a.

The cycle patterns 111 include a plurality of bits 311 (refer to FIG. 8) of the reference servo pattern 300 written to the disk 10 of the HDD 1. The sync patterns 112 include a plurality of sync bits 312 (refer to FIG. 8) of the reference servo pattern 300 written to the disk 10 of the HDD 1. The reference servo pattern 300 written to the disk 10 of the HDD 1 includes the bits 311 and the sync bits 312 arranged at a constant interval. In response to the shape of the reference servo pattern 300, the ammonite cycles 110 of the master pattern 100 according to the present exemplary embodiment includes the cycle patterns 111, formed of the bits 311 of the reference servo pattern 300, and the sync patterns 112, formed of the sync bits 312 of the reference servo pattern 300.

As illustrated in FIGS. 7 and 8, each of the sync bits 112a of the sync patterns 112 has a size equivalent to the sum of two bits 111a of the cycle patterns 111. That is, the width of each sync bit 112a of the sync patterns 112 is substantially double the width of each bit 111a of the cycle patterns 111. Accordingly, the frequency of each of the sync patterns 112 has a value substantially equivalent to the half of the frequency of each of the cycle pattern 111.

When the reference servo pattern 300 is written to the disk 10 by using the master pattern 100 and a magnet (not shown), magnetic flux of the reference servo pattern 300 formed on the disk 10 has a constant waveform. In this case, the frequency of the magnetic flux of the reference servo pattern 300 remains constant and is repeated with the same value in an area where the bits 311 are formed, but is decreased to a value corresponding to half in an area where the sync bits 312 are formed, compared to an area where the bits 311 are formed.

Thus, by making the sizes of the bits 311 and the sync bits 312 different from each other, when a final servo pattern 400 is written by using the reference servo pattern 300 formed on the disk 10, the section of the reference servo pattern 300 to be used, that is, a servo sampling section 500 (refer to FIG. 9) may be accurately specified. However, as necessary, the size of each of the sync bits 112a of the sync patterns 112 may be adjusted to be slightly larger or smaller than twice the size of each of the bits 111a of the cycle patterns 111. Accordingly, the size of each of the sync bits 312 of the reference servo pattern 300 formed on the disk 10 may be adjusted.

The ammonite cycles 110 provided in the master pattern 100 of the present exemplary embodiment do not include an alternating current (AC) erase pattern, but include the cycle patterns 111 and the sync patterns 112, thereby simplifying the manufacturing process of the master pattern 100. That is, to improve recording quality of a four burst servo pattern recorded on the disk 10, the conventional PM includes an AC erase pattern having a frequency of over twice the four burst servo pattern.

The AC erase pattern forms an accurate area of the 4 burst servo pattern and removes a direct current (DC) magnetization portion that may be generated when the four burst servo pattern is recorded on the disk 10 through the PM, thereby improving the quality of the 4 four servo pattern. However, since the AC erase pattern is provided in the PM with a size under the half of the size of the bits of the four burst servo pattern, the manufacturing of the PM is made difficult so that the time to manufacture the PM may be increased.

In consideration of the above issue, the ammonite cycles 110 provided in the master pattern 100 of the present exemplary embodiment erase the AC erase pattern portion needed to manufacture the PM and include only the cycle patterns 111 and the sync patterns 112, thereby solve the above issues.

In the writing of a reference servo pattern to a disk of the HDD by using the master pattern (S2), the reference servo pattern 300 is written to the disk 10 by using the master pattern 100 that is previously manufactured.

As illustrated in FIG. 8, in the operation S2, a method to magnetize the disk 10 is performed by arranging the master pattern 100 that is previously manufactured, close to one side of the disk 10, and simultaneously arranging a magnet (not shown) to contact another side of the master pattern 100 that is not close to the disk 10. Accordingly, the ammonite cycles 110 provided in the master pattern 100 is written to the disk 100 as the reference servo pattern 300 having the same pattern as the ammonite cycles 110.

In the writing of a final servo pattern to a disk of the HDD by using the reference servo pattern (S3), the final servo pattern 400 is written by using the reference servo pattern 300 formed on the disk 10. As illustrated in FIG. 9, the reference servo pattern 300 having the same shape as that of the ammonite cycles 110 of the master pattern 300 is written on the disk 10 after the operation S2. The process to write the final servo pattern 400 by using the reference servo pattern 300 is referred to as a servo copy process that is described below.

The HDD 1 reads the reference servo pattern 300 while following the track 12 of the disk 10 where the reference servo pattern 300 is recorded. The reference servo pattern 300 is recorded according to a predetermined frequency, that is, a clock frequency. The clock frequency of a read/write channel circuit is locked according to the preamble 16a of the reference servo pattern 300. When the clock frequency of a read/write channel circuit is locked and a servo address mark is detected, a servo gate SG signal is generated. The read/write channel circuit reads the SAM 16b and the gray code 16c from the reference servo pattern 300 read by using the read/write head 31 during which the servo gate signal is effective, and writes the final servo pattern 400 based on the read information. In particular, a section to copy the final servo pattern 400 based on the reference servo pattern 300 is referred to as a servo sampling section 500 which is specified by the sync bits 312 of the reference servo pattern 300.

According to the method of writing a servo pattern of an HDD according to the present exemplary embodiment, since the reference servo pattern 300 is written to the disk 10 of the HDD 1 by using the master pattern 100 having the ammonite cycles 10, not only the time and cost to write the reference servo pattern 300 to the disk 10 of the HDD 1 may be reduced, but the reference servo pattern 300 desired by a user may be conveniently written.

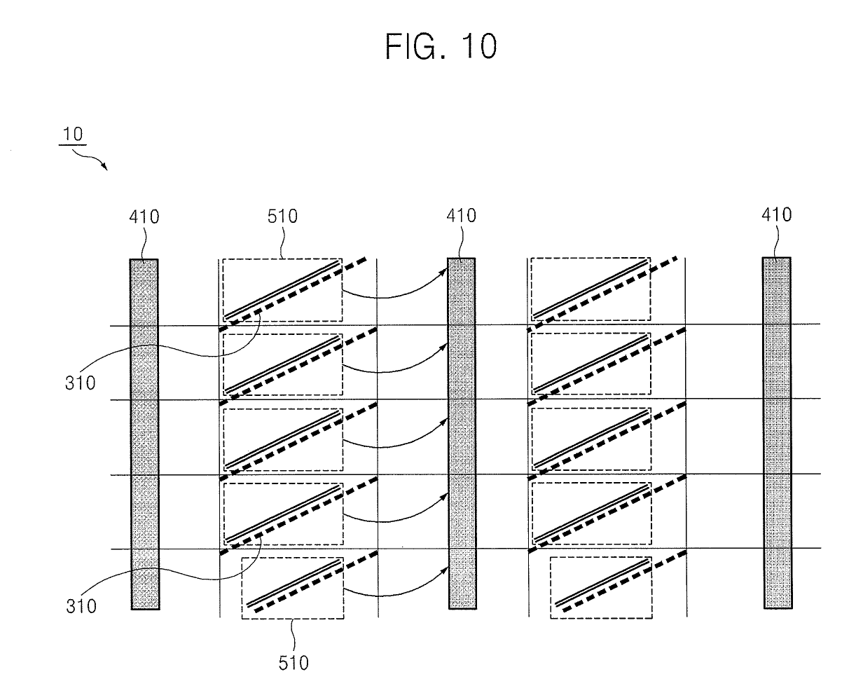

FIG. 10 schematically illustrates the principle of an operation to write a final servo pattern by using the reference servo pattern formed on a disk, according to another exemplary embodiment. Referring to FIG. 10, the method of writing a servo pattern in an HDD according to the present exemplary embodiment includes the operations of manufacturing a master pattern (not shown), writing a reference servo pattern to a disk of the HDD by using the master pattern, and writing a final servo pattern to a disk of the HDD by using the reference servo pattern.

In the present exemplary embodiment, the master pattern has a plurality of ammonite cycles (not shown) intermittently formed only in a servo sampling section 510. Since other conditions are the same as those of the above-described exemplary embodiment, detailed descriptions thereon will be omitted herein.

A reference servo pattern 310 written by using the master pattern of the present exemplary embodiment is intermittently provided only in the servo sampling section 510 on the disk 10. By using this, a servo copy process to write a final servo pattern 410 of the HDD 1 is performed so that the final servo pattern 410 may be written to the disk 10.

According to the method of writing a servo pattern of an HDD according to the present exemplary embodiment, since the ammonite cycles are intermittently provided in the master pattern, the process time to manufacture the master pattern may be reduced and further the time and cost to write the reference servo pattern 310 to the disk 10 of the HDD 1 so that the reference servo pattern 310 desired by a user may be conveniently written.

As described above, according to exemplary embodiments, since a reference servo pattern is written to a disk of an HDD by using a master pattern having a plurality of ammonite cycles, the time and cost to write a reference servo pattern to a disk of an HDD may be reduced. Furthermore, a reference servo pattern desired by a user may be conveniently written.

While exemplary embodiments have been particularly shown and described, it will be understood that various changes in form and details may be made therein without departing from the spirit and scope of the following claims.

What is claimed is:

1. A method of writing a servo pattern to a disk, the method comprising:
manufacturing a master pattern;
writing a reference servo pattern to the disk by using the master pattern and a magnet which magnetizes the disk,
wherein the master pattern comprises a plurality of ammonite cycles that have substantially the same pattern as the reference servo pattern and are radially formed from an outer circumferential limit of the disk toward an inner circumferential limit of the disk.

2. The method of claim 1, further comprising writing a final servo pattern to the disk by using the reference servo pattern, after the reference servo pattern is written.

3. The method of claim 1, wherein the reference servo pattern comprises:
a plurality of bits arranged at a regular interval; and
a plurality of sync bits formed between the plurality of bits.

4. The method of claim 1, wherein the ammonite cycles comprises:
a plurality of cycle patterns, each comprising a plurality of bits arranged at a regular interval; and
a plurality of sync patterns, each being formed between adjacent cycle patterns and each comprising a plurality of sync bits.

5. The method of claim 4, wherein a size of each of the sync bits of the sync patterns is twice of a size of each of the bits of the cycle patterns.

6. The method of claim 1, wherein the ammonite cycles are continuously formed.

7. The method of claim 6, wherein the ammonite cycles are intermittently formed only in a servo sampling section.

8. The method of claim 1, wherein the manufacturing the master pattern comprises:
coating a photoresist layer on a substrate;
exposing the photoresist layer to light;
developing the photoresist layer to selectively remove an exposed portion of the photoresist layer; and
pouring a mold onto portions of the substrate from which the photoresist layer has been removed, and hardening the mold.

9. The method of claim 8, wherein, the exposing the photoresist layer to light comprises exposing the photoresist layer using an electron beam.

10. A method of writing a servo pattern to a disk, the method comprising:
forming a master pattern comprising a plurality of ammonite cycles disposed between an outer circumferential limit of the disk and an inner circumferential limit of the disk;
writing a reference servo pattern to the disk by magnetic flux by disposing the master pattern on a first side of the disk and disposing a magnet on a second side of the disk, the reference servo pattern having a shape which is substantially the same as a shape of the master pattern;
writing a final servo pattern to the disk by a servo copy process.

11. The method of claim 10, wherein:
each of the ammonite cycles comprises a plurality of cycle patterns alternately arranged with a plurality of sync patterns;
each of the cycle patterns comprises a plurality of bits;
each of the sync patterns comprises a plurality of sync bits having a width which is twice a width of each of the plurality of bits of the cycle patterns.

12. The method of claim 10, wherein the reference servo pattern comprises a plurality of bits arranged at a regular interval, and a plurality of sync bits arranged between the plurality of bits.

13. The method of claim 10, wherein the writing the master pattern to the disk comprises:
coating a photoresist layer on a substrate;
exposing portions of the photoresist layer to light;
developing the photoresist layer to selectively remove exposed portions of the photoresist layer;
pouring a mold onto portions of the substrate from which the photoresist layer has been removed; and
hardening the mold.

14. The method of claim 13, wherein the exposing portions of the photoresist layer to light comprises exposing portions of the photoresist layer using an electron beam.
